(19) United States
(12) Patent Application Publication
(10) Pub. No.: US 2010/0270589 A1
(43) Pub. Date: Oct. 28, 2010

(54) PHOTODETECTORS CONVERTING OPTICAL SIGNAL INTO ELECTRICAL SIGNAL

(75) Inventors: Dong-Woo Suh, Daejeon (KR); Gyung-Ock Kim, Seoul (KR); Sang-Hun Kim, Daejeon (KR)

Correspondence Address: AMPACC Law Group, 3500 188th Street S.W., Suite 103, Lynnwood, WA, 98037, US

(73) Assignee: Electronics and Telecommunications Research Institute, Daejeon (KR)

(21) Appl. No.: 12/741,258

(22) PCT Filed: May 8, 2008
(86) PCT No.: PCT/KR08/02599

§ 371 Date: May 4, 2010

(30) Foreign Application Priority Data
Nov. 5, 2007 (KR) 10-2007-0111912

(51) Int. Cl. H01L 31/10; H01L 31/0248

(52) U.S. Cl. 257/184; 257/E31.053; 257/E31.002

(57) ABSTRACT

Provided is a photodetector converting an optical signal into an electrical signal. The photodetector includes: a plurality of semiconductor layers sequentially stacked on a substrate; a plurality of photoelectric conversion units formed in the semiconductor layers, respectively, and having different spectral sensitivities from each other; and buffer layers interposed between the adjacent semiconductor layers, respectively. Each of the buffer layers alleviates stress between the adjacent semiconductor layers.

### TECHNICAL FIELD

The present invention disclosed herein relates to a semiconductor device, and more particularly, to a photodetector converting an optical signal into an electrical signal.

The present invention has been derived from research undertaken as a part of the information technology (IT) R & D program of the Ministry of Information and Communication and the Institution for Information Technology Advancement of (MIC/IITA)[2006-S-007-02], silicon-based very high speed optical interconnection IC.

### BACKGROUND ART

A photodetector may be a device converting an external optical signal into an electrical signal. Recently, various technical fields using light are under remarkable developments. Examples of the technical fields may be an optical communication using light as a medium for exchanging information, and image sensors converting light reflected from an object into an electrical signal. A photodetector is a very important component converting light into an electrical signal in various technical fields.

Typically, a photodetector may employ a photodiode that converts an optical signal into an electrical signal. After an external light is incident to a depletion region of a photodiode to generate electron-hole pairs, the electrons (or holes) are extracted from the pairs. Consequently, an optical signal is converted into an electrical signal by extracting the electrons (or holes). At this point, according to intensity of absorbed light, an amount of the created electron-hole pairs may vary. That is, as intensity of absorbed light increases, an amount of created electron-hole pairs increases. Therefore, an electrical signal corresponding to intensity of light can be outputted.

As a semiconductor industry is highly developed, to expand applicable technical fields of photodetectors and to increase productivity of photodetectors, demands for photodetectors having the high degree of integration, multi-functionality, and light weight grow. Currently, many researches are actively under development in order to satisfy the above demands.

### DISCLOSURE OF INVENTION

### Technical Problem

The present invention provides a photodetector capable of detecting intensities of sub lights having respectively different wavelengths in an external light.

The present invention also provides a photodetector capable of detecting each of intensities of a plurality of sub lights in a limited region.

### Technical Solution

Embodiments of the present invention provide photodetector. The photodetector may include: a plurality of semiconductor layers sequentially stacked on a substrate; a plurality of photoelectric conversion units formed in the semiconductor layers, respectively, and having different spectral sensitivities from each other; and buffer layers interposed between the adjacent semiconductor layers, respectively. Each of the buffer layers alleviates stress between the adjacent semiconductor layers.

In some embodiments, the lowermost semiconductor layer among the semiconductor layers may be formed of a first semiconductor, and the uppermost semiconductor layer among the semiconductor layers may be formed of a second semiconductor. At least one semiconductor layer interposed between the lowest and uppermost semiconductor layers may include a hetero-semiconductor having the first and second semi-conductors.

In other embodiments, the lowermost semiconductor layer may be formed of silicon; the uppermost semiconductor layer may be formed of germanium; and the interposed semiconductor layer may be formed of silicon-germanium.

In still other embodiments, the entire interposed semiconductor layer may include a uniform a germanium concentration.

In even other embodiments, each of the buffer layers may be formed of silicon-germanium, and a germanium concentration of each of the buffer layers gradually increases farther away from a bottom surface of each of the buffer layers.

In yet other embodiments, a germanium concentration at the bottom surface of each of the buffer layers may be the same as a germanium concentration of the semiconductor layer right below each of the buffer layers; and a germanium concentration at the top surface of each of the buffer layers may be the same as a germanium concentration of the semiconductor layer right above each of the buffer layers.

In further embodiments, each of the photoelectric conversion units may include an N-doped region and a P-doped region in each of the semiconductor layers.

In still further embodiments, each of the photoelectric conversion units may further include an intrinsic region interposed between the N-doped region and the P-doped region.

In even further embodiments, the lowermost semiconductor layer among the semiconductor layers may be formed of a first semiconductor, the uppermost semiconductor layer among the semiconductor layers may be formed of a second semiconductor, and a plurality of the semiconductor layers may be interposed between the uppermost semiconductor layer and the lowermost semiconductor layer. Each of the interposed semiconductor may be formed of a hetero-semiconductor including the first and second semiconductors. The interposed semiconductor layers may have different second semiconductor concentrations from each other.

In yet further embodiments, the lowermost semiconductor layer may be formed of silicon; the uppermost semiconductor layer may be formed of germanium; and the interposed semiconductor layers may be formed of silicon-germanium. A germanium concentration of each of the interposed semiconductor layers may be uniform. A germanium concentration of an interposed semiconductor layer relatively close to the lowermost semiconductor layer among the interposed semiconductor layers may be less than a germanium concentration of an interposed semiconductor layer relatively close to the uppermost semiconductor layer.

In yet further embodiments, the photodetector may further include a signal detection circuit electrically connected to the photoelectric conversion units.

In yet further embodiments, an external light including a plurality of sub lights with respectively different wavelengths may be incident to the photoelectric conversion units. In this case, the signal detection circuit may include: detectors respectively connected to the photoelectric conversion units and detecting intensity of light absorbed in each of the photoelectric conversion units as an electrical signal; and an operator calculating intensity of each of sub lights by means of at least signals extracted by the detectors, absorption coefficients according to wavelengths of the semiconductor layers, and thicknesses of the semiconductor layers.

In yet further embodiments, a sub light having the longest wavelength among the sub lights may be absorbed by the photoelectric conversion unit at the highest layer among the photoelectric conversion units, and a sub light having a shorter wavelength than the longest wavelength among the sub lights may be absorbed by at least the photoelectric conversion unit at the highest layer and the photoelectric conversion unit right below the conversion unit at the highest layer.

In other embodiments of the present invention, a photodetector may include: a plurality of semiconductor layers sequetially stacked on a substrate; a plurality of photoelectric conversion units formed in the semiconductor layers, respectively; and buffer layers interposed between the adjacent semiconductor layers, respectively. Each of the buffer layers alleviates stress between the adjacent semiconductor layers and the semiconductor layers have different energy band gaps from each other.

In some embodiments, energy band gaps of the semiconductor layers may decrease farther away from the substrate.

In other embodiments, the lowermost semiconductor layer among the semiconductor layers may be formed of silicon; the uppermost semiconductor layer among the semiconductor layers may be formed of germanium; and at least one semiconductor layer interposed between the lowest and uppermost semiconductor layers may be formed of silicon-germanium.

In still other embodiments, each of the photoelectric conversion units may include an N-doped region and a P-doped region in each of the semiconductor layers and an intrinsic region interposed between the N-doped region and the P-doped region.

### ADVANTAGEOUS EFFECTS

A photodetector according to the present invention includes a plurality of photoelectric conversion units sequetially stacked on a substrate. The photoelectric conversion units have different spectral sensitivities from each other, such that intensities of sub lights having different wavelengths from each other can be calculated. Additionally, semiconductor layers having the photoelectric conversion units alleviate their stresses by using buffer layers interposed therebetween. Accordingly, the sufficient thickness of the photoelectric conversion units can be obtained by satisfactorily thickly forming the semiconductor layers.

### BRIEF DESCRIPTION OF THE DRAWINGS

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a sectional view of a photodetector according to an embodiment of the present invention;

FIG. 2 is a conceptual view illustrating an operational principle of a photodetector according to an embodiment of the present invention; and

FIGS. 3 through 5 are sectional views illustrating a method of forming a photodetector according to an embodiment of the present invention.

### BEST MODE FOR CARRYING OUT THE INVENTION

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. It will also be understood that when a layer (or film) is referred to as being on?another layer or substrate, it can be directly on the other layer or substrate, or intervening layers may also be present. Further, it will be understood that when a layer is referred to as being under?another layer, it can be directly under, and one or more intervening layers may also be present. In addition, it will also be understood that when a layer is referred to as being between?two layers, it can be the only layer between the two layers, or one or more intervening layers may also be present. Like reference numerals refer to like elements throughout.

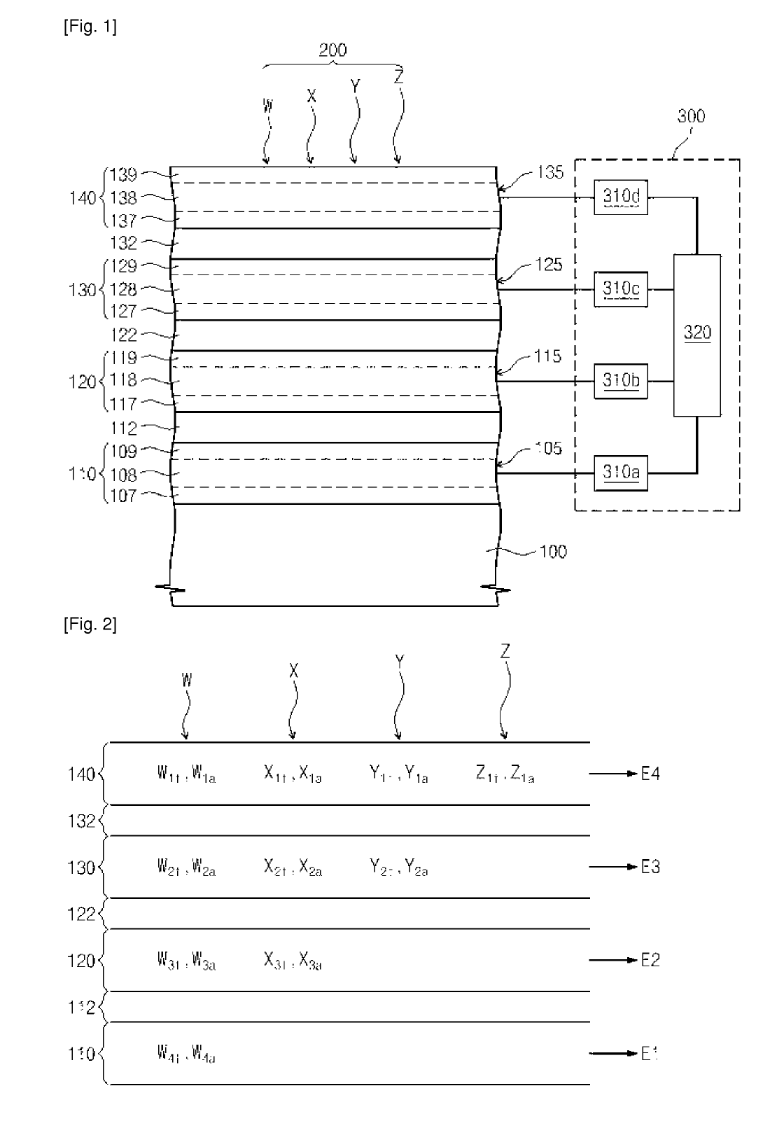

FIG. 1 is a sectional view of a photodetector according to an embodiment of the present invention.

Referring to FIG. 1, the photodetector of the present invention includes a plurality of semiconductor layers 105, 115, 125, and 135, which are sequentially stacked on a substrate 100. A first semiconductor layer 105, a second semiconductor layer 115, a third semiconductor layer 125, and a fourth semiconductor layer 135 are shown in FIG. 1. Unlike this, three or more than five semiconductor layers may be stacked on the substrate 100. According to one embodiment of the present invention, there may be more than third-layered semiconductor layers.

A plurality of photoelectric conversion units 110, 120, 130, and 140 are disposed in the semiconductor layers 105, 115, 125, and 135, respectively. That is, a first photoelectric conversion unit 110 is disposed in the first semiconductor layer 105. A second photoelectric conversion unit 120 is disposed in the second semiconductor layer 120. A third photoelectric conversion unit 125 is disposed in the third semiconductor layer 125. A fourth photoelectric conversion unit 135 is disposed in the fourth semiconductor layer 140. The photoelectric conversion units 110, 120, 130, and 140 convert an optical signal into an electrical signal. The photoelectric conversion units 110, 120, 130, and 140 have different spectral sensitivities from each other. For example, each of the photoelectric conversion units 110, 120, 130, and 140 can absorb lights having wavelengths less than a specific wavelength. At this point, the specific wavelengths of the photoelectric conversion units 110, 120, 130, and 140 may be different wavelengths from each other.

The first photoelectric conversion unit 110 may be disposed with a photodiode shape in the first semiconductor layer 105. The first photoelectric conversion unit 110 includes a first doped region 107 doped with a first dopant, and a second doped region 109 doped with a second dopant in the first semiconductor layer 105. One of the first and second doped regions 107 and 109 is an N-doped region, and the other is a P-doped region. The first photoelectric conversion unit 110 may further include an intrinsic region 108 interposed between the first and second doped regions 107 and 109. The first photoelectric conversion unit 110 includes a depletion region.

Likewise, the second, third, and fourth photoelectric conversion units 120, 130, and 140 may be formed with a photodiode shape in the second, third, and fourth semiconductor layers 115, 125, and 135, respectively. In more detail, the second photoelectric conversion unit 120 includes a first doped region 117 and a second doped region 119, and may further include an intrinsic region 118 interposed between the first and second doped regions 117 and 119. One of the first and second doped regions 117 and 119 is an N-doped region, and the other is a P-doped region in the second semiconductor layer 115. The third photoelectric conversion unit 130 includes a first doped region 127 and a second doped region 129, and may further include an intrinsic region 128 interposed between the first and second doped regions 127 and 129. One of the first and second doped regions 127 and 129 is an N-doped region, and the other is a P-doped region in the third semiconductor layer 125. The fourth photoelectric conversion unit 140 includes a first doped region 137 and a second doped region 139, and may further include an intrinsic region 138 interposed between the first and second doped regions 137 and 139. One of the first and second doped regions 137 and 139 is an N-doped region, and the other is a P-doped region in the fourth semiconductor layer 135.

The semiconductor layers 105, 115, 125, and 135 may have different energy band gaps from each other. Therefore, the first to fourth photoelectric conversion units 110, 120, 130, and 140 may have different spectral sensitivities from each other. Energy band gaps of the semiconductor layers 105, 115, 125, and 135 may be reduced as the layers become farther away from the substrate 100. That is, the energy band gap of the lowermost first semiconductor layer 105 is the largest one among the energy band gaps of the semiconductor layers 105, 115, 125, and 135, and the energy band gap of the uppermost fourth semiconductor layer 135 is the smallest one among the energy band gaps of the semiconductor layers 105, 115, 125 and 135.

The lowermost first semiconductor layer 105 is formed of a first semiconductor, and the uppermost fourth semiconductor layer 135 is formed of a second semiconductor. At this point, the second and third semiconductor layers 115 and 125 interposed between the first and fourth semiconductor layers 105 and 135 may be formed of a hetero-semiconductor including the first and second semiconductors. Concentrations of the second semiconductors in the interposed semiconductors 115 and 125 may increase as the layers become farther away from the substrate 100. At this point, the concentration of the second semiconductor in the second semiconductor layer 115 may be uniform over an entire region of the second semiconductor layer 115, and the concentration of the second semiconductor in the third semiconductor layer 125 may be uniform over an entire region of the third semiconductor layer 125.

The lowermost first semiconductor layer 105 may be formed of silicon, and the uppermost fourth semiconductor layer 135 may be formed of germanium. The second and third semiconductor layers 115 and 125 interposed between the first and fourth semiconductor layers 105 and 135 may be formed of silicon-germanium. At this point, a germanium concentration of the third semiconductor layer 125 is higher than that of the second semiconductor layer 115. Energy band gap of germanium is lower than that of silicon. Energy band gap of silicon-germanium varies according to a germanium concentration. That is, as a germanium concentration increases, an energy band gap of silicon-germanium decreases. Accordingly, as the layers become farther away from the substrate 100, energy band gaps of the semiconductor layers 105, 115, 125, and 135 may decrease.

Buffer layers 112, 122, and 132 are respectively interposed between the semiconductor layers 105, 115, 125, and 135. That is, the first buffer layer 112 is interposed between the first and second semiconductor layers 105 and 115. The second buffer layer 122 is interposed between the second third semiconductor layers 115 and 125. The third buffer layer 132 is interposed between the third and fourth semiconductor layers 125 and 135.

As described above, the semiconductor layers 105, 115, 125, and 135 are formed of different kinds and/or different composition ratios of semiconductors from each other. Accordingly, the sizes of the lattices of the semiconductor layers 105, 115, 125, and 135 are different from each other. Therefore, stress may occur between the semiconductor layers 105, 115, 125, and 135. At this point, the buffer layers 112, 122, and 132 alleviate stresses between the semiconductor layers 105, 115, 125, and 135. In more detail, the buffer layers 112, 122, and 132 may be formed of silicon-germanium. A germanium concentration of each of the buffer layers 112, 122, and 132 may gradually increase as it becomes higher from the bottom surface of each of the buffer layers 112, 122, and 132 toward the upper surface of each of the buffer layers 112, 112 and 132.

A germanium concentration at the bottom surface of each of the buffer layers 112, 122, and 132 may be identical to that of the semiconductor layer 105, 115, or 125 right below the each of the buffer layers 112, 122, and 132. A germanium concentration at the top surface of the each of the buffer layers 112, 122, and 132 may be identical to that of the semiconductor layer 115, 125, or 135 right above the each of the buffer layers 112, 122 and 132. For example, germanium concentration at the bottom surface of the first buffer layer 112 may be the same as a germanium concentration of the first semiconductor layer 105 formed of silicon (i.e., zero). A germanium concentration at the upper surface of the first buffer layer 112 may be the same as a germanium concetration of the second semiconductor layer 115. Germanium concentration at the bottom surface and the top surface of the second buffer layer 122 may be identical to those of the second third semiconductor layers 115 and 125, respectively. Germanium concentrations at the bottom surface and the top surface of the third buffer layer 132 may be identical to those of the third and fourth semiconductor layers 125 and 135, respectively. Germanium concentrations in the buffer layers 112, 122, and 132 gradually are changed, such that stresses between the semiconductor layers 105, 115, 125, and 135 having different sizes of lattices from each other can be alleviated.

Although an external light 200 including a plurality of sub lights W, X, Y, and Z having different wavelengths from each other is incident, the photodetector can respectively extract intensities of the sub lights W, X, Y, and Z by means of the photoelectric conversion units 110, 120, 130, and 140.

The photodetector of the present invention may further include a signal detection circuit 300 that is electrically connected to the photoelectric conversion units 110, 120, 130, and 140. The signal detection circuit 300 includes a plurality of detectors 310a, 310b, 310c, and 310d, and an operator 320. The detectors 310a, 310b, 310c, and 310d are respectively electrically connected to the photoelectric conversion units 110, 120, 130, and 140. The first detector 310a extracts an electrical signal from intensity of light absorbed in the first photoelectric conversion unit 110. Likewise, the second, third, and fourth detectors 310b, 310c, and 310d extract electrical signals from the second, third, and fourth photoelectric conversion units 120, 130, and 140. The operator 320 respectively extracts intensities of the sub lights W, X, Y, and Z by using at least signals extracted by detectors 310a, 310b, 310c, and 310d, absorption coefficients according to wavelengths of the semiconductor layers 105, 115, 125, and 135, and thicknesses of the photoelectric conversion units 110, 120, 130, and 140.

Next, operational principles of a photodetector according to an embodiment of the present invention will be described with reference to the drawings.

FIG. 2 is a conceptual view illustrating an operational principle of a photodetector according to an embodiment of the present invention.

Referring to FIGS. 1 and 2, an external light 200 including a plurality of sub lights W, X, Y, and Z having different wavelengths from each other is incident to the photoelectric conversion units 110, 120, 130, and 140. The first sub light W has the shortest wavelength, and the second sub light X has a longer wavelength than that of the first sub light W. The third sub light Y has a longer wavelength than that of the second sub light X, and the fourth sub light Z has a longer wavelength than that of the third sub light Y. The fourth sub light Z has the longest wavelength. That is, the first sub light W has the relatively highest energy, and the fourth sub light Z has the relatively lowest energy. The second sub light X has energy between energies of the first and third sub lights W and Y. The third sub light Y has energy between energies of the second and fourth sub lights X and Z.

The fourth semiconductor layer 135 has the smallest energy band gap among the semiconductor layers 105, 115, 125, and 135. The fourth semiconductor layer 135 has an energy band gap identical to or less than energy of the fourth sub light Z. The third semiconductor layer 125 has an energy band gap greater than energy of the forth sub light Z, and identical to or less than energy of the third sub light Y. The second semiconductor layer 115 has an energy band gap greater than energy of the third sub light Y, and identical to or less than energy of the second sub light X. The first semi-conductor layer 105 has an energy band gap greater than energy of the second sub light X, and identical to or less than energy of the first sub light W. The semiconductor layers 105, 115, 125, and 135 have absorption coefficients with respect to the sub lights W, X, Y, and Z. The absorption coefficients may be determined by a semiconductor composition ratio in the semiconductor layers 105, 115, 125, and 135. The absorption coefficients of the semiconductor layers 105, 115, 125, and 135 may vary according to the wavelengths of the sub lights W, X, Y, and Z.

Because the sub lights W, X, Y, and Z include energies identical to or more than the energy band gap of the fourth semiconductor layer 135, the fourth photoelectric conversion unit 140 absorbs portions of the first to fourth sub lights W, X, Y, and Z. Because the first to third sub lights W, X, and Y have energies identical to or more than an energy band gap of the third semiconductor layer 125, the third photoelectric conversion unit 130 in the third semiconductor layer 125 absorbs portions of the first to third sub lights W, X, and Y. At this point, because the fourth sub light Z has energy less than an energy band gap of the third semiconductor layer 125, the third photoelectric conversion unit 130 does not absorb the fourth sub light Z. Similarly to this, the second photoelectric conversion unit 120 in the second semiconductor layer 115 absorbs portions of the first and second sub lights W and X, but does not absorb the third and fourth sub lights Y and Z. The first photoelectric conversion unit 110 in the first semiconductor layer 105 absorbs a portion of the first sub light W. That is, the first photoelectric conversion unit 110 does not absorb the second to fourth sub lights X, Y, and Z.

Next, a method of extracting intensities of the sub lights W, X, Y, and Z by using the photodetector will be described in more detail with reference to the drawings.

Once the first sub light W is incident to the fourth photoelectric conversion unit 140, a portion of the first sub light W is absorbed in the fourth photoelectric conversion unit 140, and the remaining portion is transmitted through the fourth photoelectric conversion unit 140. A portion of the first sub light W transmitted through the fourth photoelectric conversion unit 140 is partially again absorbed in the third photoelectric conversion unit 130, and its remaining portion is transmitted through the third photoelectric conversion unit 130. Likewise, a portion of the first sub light W transmitted through the third photoelectric conversion unit 130 is partially absorbed in the second photoelectric conversion unit 120, and its remaining portion is transmitted through the second photoelectric conversion unit 120. A portion of the first sub light W transmitted through the second photoelectric conversion unit 120 is partially absorbed in the first photoelectric conversion unit 110, and its remaining portion is transmitted through the first photoelectric conversion unit 110.

The intensity of the first sub light W absorbed in the fourth photoelectric conversion unit 140 is defined as a first absorption intensity W₁ₐ, and the intensity of the first sub light W transmitted through the fourth photoelectric conversion unit 140 is defined as a first transmission intensity W₁ₜ, of the first sub light W. The intensity of the first sub light W absorbed in the third photoelectric conversion unit 130 is defined as a second absorption intensity W₂ₐ, and the intensity of the first sub light W transmitted through the third photoelectric conversion unit 130 is defined as a second transmission intensity W₂ₜ of the first sub light W. The intensity of the first sub light W absorbed in the second photoelectric conversion unit 120 is defined as a third absorption intensity W₃ₐ of the first sub light W, and the intensity of the first sub light W transmitted through the second photoelectric conversion unit 120 is defined as a third transmission intensity W₃ₜ, of the first sub light W. The intensity of the first sub light W absorbed in the first photoelectric conversion unit 110 is defined as a fourth absorption intensity W₄ₐ of the first sub light W, and the intensity of the first sub light W transmitted through the first photoelectric conversion unit 110 is defined as a fourth transmission intensity W₄ₜ of the first sub light W.

Likewise, a first absorption intensity X₁ₐ of the second sub light X corresponds to the intensity of the second sub light X absorbed in the fourth photoelectric conversion unit 140, and a first transmission intensity X₁ₜ, of the second sub light X corresponds to the intensity of the second sub light X transmitted through the fourth photoelectric conversion unit 140. A second absorption intensity X₂ₐ of the second sub light X corresponds to the intensity of the second sub light X absorbed in the third photoelectric conversion unit 130, and a second transmission intensity X₂ₜ of the second sub light X corresponds to the intensity of the second sub light X transmitted through the third photoelectric conversion unit 130. A third absorption intensity X₃ₐ of the second sub light X corresponds to the intensity of the second sub light X absorbed in the second photoelectric conversion unit 140, and a third transmission intensity X₃ₜ, of the second sub light X corresponds to the intensity of the second sub light X transmitted through the second photoelectric conversion unit 140. A portion of the second sub light X transmitted through second photoelectric conversion unit 120 is not absorbed in the first photoelectric conversion unit 110.

A first absorption intensity Y₁ₐ of the third sub light Y corresponds to the intensity of the third sub light Y absorbed in the fourth photoelectric conversion unit 140, and a first transmission intensity Y₁ₜ, of the third sub light Y corresponds to the intensity of the third sub light Y transmitted through the fourth photoelectric conversion unit 140. A second absorption intensity Y₂ₐ of the third sub light Y corresponds to the intensity of the third sub light Y absorbed in the third photoelectric conversion unit 130, and a second transmission intensity Y₂ₜ of the third sub light Y corresponds to the intensity of the third sub light Y transmitted through the third photoelectric conversion unit 130. The third sub light Y transmitted through the third photoelectric conversion unit 130 is not absorbed in the second and first photoelectric conversion units 120 and 110.

A first absorption intensity Z₁ₐ of the fourth sub light Z corresponds to the intensity of the fourth sub light Z absorbed in the fourth photoelectric conversion unit 140, and a first transmission intensity Z₁ₜ, of the fourth sub light Z corresponds to the intensity of the fourth sub light Z transmitted through the fourth photoelectric conversion unit 140. The fourth sub light Z transmitted through the fourth photoelectric conversion unit 140 is not absorbed in the third, second, and first photoelectric conversion units 130, 120, and 110.

Relationship between an initial intensity (i.e., intensity before incident) of the first sub light W and the first transmission intensity W₁ₜ, of the first sub light W is expressed based on the following Equation 1.

W₀=W₁ₜ·e^{A}^{_{W1}}^{·d1} [Equation 1]

where W₀ represents an initial intensity of the first sub light W, and A_{W1} is an absorption coefficient with respect to the first sub light W in a region through which a component having the first transmission intensity W₁ₜ, of the first sub light W passes. That is, A_{W1} is an absorption coefficient of the fourth semiconductor layer 135 with respect to the first sub light W. d1 is a distance that a component having the first transmission intensity W₁ₜ, of the first sub light W passes. That is, d1 is the thickness of the fourth semiconductor layer 135.

Likewise, relationships between the first and second transmission intensities W₁ₜ, and W₂ₜ, between the second and third transmission intensities W₂ₜ, and W₃ₜ, and between third and fourth transmission intensities W₃ₜ and W₄ₜ, are expressed based on the following Equation 2.

[Equation 2]

W₁ₜ=W₂ₜ·e^{A}^{_{W2}}^{·d2} (1)

W₂ₜ=W₃ₜ·e^{A}^{_{W3}}^{·d3} (2)

W₃ₜ=W₄ₜ·e^{A}^{_{W4}}^{·d4} (3)

where A_{W2} is an absorption coefficient of the third semiconductor 125 with respect to the first sub light W. A_{W3} is an absorption coefficient of the second semiconductor layer 115 with respect to the first sub light W. A_{W4} is an absorption coefficient of the first semiconductor layer 105 with respect to the first sub light W. d2, d3, and d4 represent the thickness of the third semiconductor layer 125, the thickness of the second semiconductor layer 115, and the thickness of the first semiconductor layer 105, respectively. (1), (2), and (3) of the above Equation 2 represent a relational expression between the first and second transmission intensities W₁ₜ and W₂ₜ, a relational expression between the second and third transmission intensities W₂ₜ and W₃ₜ, and a relational expression between the third and fourth transmission intensities W₃ₜ and W₄ₜ, respectively.

When the first, second, and third transmission intensities W₁ₜ, W₂ₜ and W₃ₜ of the first sub light W disposed in Equation 2 are substituted into Equation 1, the next Equation 3 can be obtained.

$$\begin{matrix}{W}_{0} = {W}_{4 t} \cdot {e}^{{A}_{w 1} \cdot d 1 + {A}_{w 2} \cdot d 2 + {A}_{w 3} \cdot d 3 + {A}_{w 4} \cdot d 4} \\ = {W}_{4 t} \cdot {\prod }_{i = 1}^{4} {e}^{( {A}_{w i} \cdot d i )}\end{matrix} \qquad [ Equation 3 ]$$

As expressed in Equation 3, the initial intensity W₀ of the first sub light W is determined by the thicknesses d1, d2, d3, and d4 of the semiconductor layers 135, 125, 115, and 105 where the first sub light W is absorbed, absorption coefficients A_{W1}, A_{W2}, A_{W3}, and A_{W4} for the first sub light W, and transmission intensity (i.e., the fourth transmission intensity W₄ₜ) in a semiconductor layer (i.e., the lowermost first semiconductor layer 105) where the first sub light W is absorbed lastly. The first photoelectric conversion unit 110 in the first semiconductor layer 105 only absorbs the first sub light W. Accordingly, a first signal E1 extracted by the first photoelectric conversion unit 110 corresponds to the fourth absorption intensity W₄ₐ of the first sub light W.

The fourth transmission intensity W₄ₜ can be obtained based on the following Equation 4 through the fourth absorption intensity W₄ₐ of the first sub light W and the absorption coefficient A_{W4} for the first sub light W of the semiconductor layer 105.

$${W}_{4 t} = ( \frac{1}{{e}^{{A}_{w 4} \cdot d 4} - 1} ) \cdot {W}_{4 a} \qquad [ Equation 4 ]$$

When the above Equation 4 is substituted into Equation 3, the following Equation 5 can be obtained.

$${W}_{0} = ( \frac{1}{{e}^{{A}_{w 4} \cdot d 4} - 1} ) \cdot {W}_{4 a} \cdot {\prod }_{i = 1}^{4} {e}^{( {A}_{w i} \cdot d i )} \qquad [ Equation 5 ]$$

The fourth absorption intensity W₄ₐ of the first sub light W corresponds to the first signal E1. Accordingly, the fourth absorption intensity W₄ₐ of the first sub light W can be replaced with the first signal E1. Consequently, relationship between the initial intensity W₀ of the first sub light W and the first signal E1 can be obtained as the following Equation 6.

$$\begin{matrix}Electrical \\ signal for {W}_{0}\end{matrix} = ( \frac{1}{{e}^{{A}_{w 4} \cdot d 4} - 1} ) \cdot {E}_{1} \cdot {\prod }_{i = 1}^{4} {e}^{{A}_{w i} \cdot d i} \qquad [ Equation 6 ]$$

Consequently, an electrical signal for the initial intensity W₀ of the first sub light W can be obtained from the first photoelectric conversion unit 110 absorbing only the first sub light W.

A portion of the first sub light W and a portion of the second sub light X are absorbed by the second photoelectric conversion unit 120. That is, a second signal E2 extracted from the second photoelectric conversion unit 120 is an electrical signal for the sum of the third absorption intensity W₃ₐ of the first sub light W and the third absorption intensity X₃ₐ of the second sub light X. The sum of the third absorption intensity W₃ₐ and the third transmission intensity W₃ₜ of the first sub light W is the same as the second transmission intensity W₂ₜ of the first sub light W. Accordingly, the third absorption intensity W₃ₐ of the first sub light W is a result after the second transmission intensity W₂ₜ of the first sub light W is subtracted by the third transmission intensity W₃ₜ of the first sub light W. consequently, the third absorption intensity W₃ₐ of the first sub light W may be expressed in a function of the fourth absorption intensity W₄ₐ of the first sub light W by means of (2) and (3) of the above Equation 2 and the above Equation 4. This is expressed in the following Equation 7.

$${W}_{3 a} = ( \frac{{e}^{{A}_{w 4} \cdot d 4}}{{e}^{{A}_{w 4} \cdot d 4} - 1} ) \cdot {W}_{4 a} \cdot ( {e}^{{A}_{w 3} \cdot d 3} - 1 ) \qquad [ Equation 7 ]$$

As mentioned above, the second signal E2 is an electrical signal for the sum of the third absorption intensity W₃ₐ of the first sub light W and the third absorption intensity X₃ₐ of the second sub light X. Accordingly, the third absorption intensity W₃ₐ of the second sub light X may be expressed in a function of the first signal E1 and the second signal E2 by using the above Equation 7. This is expressed in the following Equation 8.

$$\begin{matrix}\begin{matrix}Electrical \\ signal for {X}_{3 a}\end{matrix} = E 2 - \begin{matrix}Electrical \\ signal for {W}_{3 a}\end{matrix} \\ = E 2 - ( \frac{{e}^{{A}_{w 4} \cdot d 4}}{{e}^{{A}_{w 4} \cdot d 4} - 1} ) \cdot \\ E 1 \cdot ( {e}^{{A}_{w 3} \cdot d 3} - 1 )\end{matrix} \qquad [ Equation 8 ]$$

As described in the above Equation 5, as the initial intensity W₀ of the first sub light W is expressed in a function of the fourth absorption intensity W₄ₐ, the initial intensity of the second sub light X may be expressed in a function of the third absorption intensity X₃ₐ of the second sub light X. This is expressed in the following Equation 9.

$${X}_{0} = ( \frac{1}{{e}^{{A}_{x 3} \cdot d 3} - 1} ) \cdot {X}_{3 a} \cdot {\prod }_{i = 1}^{3} {e}^{( {A}_{x i} \cdot d i )} \qquad [ Equation 9 ]$$

where X₀ represents an initial intensity of the second sub light X. Aₓ₁ is an absorption coefficient of the fourth semiconductor layer 135 with respect to the second sub light X. Aₓ₂ is an absorption coefficient of the third semiconductor layer 125 with respect to the second sub light X. Aₓ₃ is an absorption coefficient of the second semiconductor layer 115 with respect to the second sub light X.

From the above Equations 8 and 9, an electrical signal for the initial signal X₀ of the second sub light X can be calculated.

A third signal E3 extracted from the third photoelectric conversion unit 130 is an electrical signal for the sum of the second absorption intensity W₂ₐ of the first sub light W, the second absorption intensity X₂ₐ of the second sub light X, and the second absorption intensity Y₂ₐ of the third sub light Y. By using the above Equations and the relational expression between transmission and absorption intensities of the third sub light Y, which correspond to the above Equation, the initial intensity of the third sub light Y may be expressed in the relational expression of the first, second, and third signals E1, E2, and E3. At this point, the relational Equation expressing the third sub light Y includes absorption coefficients and thicknesses for the third sub light Y of the semiconductor layers 135 and 125 where the third sub light Y passes.

The fourth signal E4 extracted from the fourth photoelectric conversion unit 140 is an electrical signal for the sum of the third absorption intensities W₁ₐ, X₁ₐ, Y₁ₐ, and Z₁ₐ of the first to fourth sub lights W, X, Y, and Z. By using the above Equations and the relational expression between transmission and absorption intensities of the fourth sub light Z, which correspond to the above Equation, the initial intensity of the fourth sub light Z may be expressed in the relational expression of the first to fourth signals E1, E2, E3, and E4. At this point, the relational Equation expressing the fourth sub light Z includes absorption coefficients and thicknesses for the fourth sub light Z of the semiconductor layer 135 where the fourth sub light Z passes.

The operator 320 of the signal detection circuit 300 calculates initial intensities of the sub lights W, X, Y, and Z by using the first to fourth signals E1, E2, E3, and E4 and absorption coefficients and thicknesses for the sub light W, X, Y, and Z of the semiconductor layers 105, 115, 125, and 135. The calculator 320 can calculates the initial intensities by using the above Equations corresponding to each of the sub lights W, X, Y, and Z.

The absorption coefficients and the thicknesses of the semiconductor layers 105, 115, 125, and 135 may be circuited in the operator 320. Unlike this, the signal detection signal 300 includes a storage unit, and the storage unit can store the absorption coefficients and the thicknesses of the semiconductor layers 105, 115, 125, and 135. In this case, the operator 320 uses the stored absorption coefficients and the thicknesses to calculate the initial intensities of the sub lights W, X, Y, and Z. The storage unit may include non-volatile memory cells.

On the other hand, the sub lights W, X, Y, and Z penetrate the buffer layers 112, 122, and 132. The buffer layers 112, 122, and 132 may have absorption coefficients for the sub light W, X, Y, and Z. If the thicknesses of the buffer layers 112, 122, and 132 are thin, it may be regarded that all the sub lights W, X, Y, and Z does not absorbed by the buffer layers 112, 122, and 132 and transmitted.

Unlike this, if the thicknesses of the buffer layers 112, 122, and 132 are thick, a portion of the sub lights W, X, Y, and Z may be absorbed. In this case, initial intensities of the sub lights W, X, Y, and Z calculated by the above Equations may require compensation. The compensation by using the buffer layers 112, 122, and 132 will be described with reference to the following Equation 10.

W₁ₜ=W₂ₜ·e^{A}^{_{W2}}^{·d2+A}^{_{BW(132)}}^{·d}^{_{BW(132)}}

W₂ₜ=W₃ₜ·e^{A}^{_{W3}}^{·d3+A}^{_{BW(122)}}^{·d}^{_{BW(122)}}

W₃ₜ=W₄ₜ·e^{A}^{_{W4}}^{·d4+A}^{_{BW(112)}}^{·d}^{_{BW(112)}} [Equation 10]

where A_{BW(112)} is an absorption coefficient of the first buffer layer 112 with respect to the first sub light W. A_{BW(122)} is an absorption coefficient of the second buffer layer 122 with respect to the first sub light W. A_{BW(132)} is an absorption coefficient of the third buffer layer 132 with respect to the first sub light W. d_{BW(112)} is the thickness of the first buffer layer 112, d_{BW(122)} is the thickness of the second buffer layer 122, and d_{BW(132)} is the thickness of the third buffer layer 132.

In a case where the first sub light W is respectively absorbed in the buffer layers 112, 122, and 132, relational expression between the transmission intensities W₁ₜ, W₂ₜ, W₃ₜ, and W₄ₜ of the first sub light W can be compensated like the above Equation 10. By using the above Equation 10 and Equations corresponding to Equation 10 of the second to fourth sub lights X, Y, and Z, obtained is an electrical signal for initial intensities of the sub lights W, X, Y, and Z with compensation for the buffer layers 112, 122, and 132.

According to the above photodetector, the photoelectric conversion units 110, 120, 130, and 140 having different spectral sensitivities from each other are sequentially stacked. Accordingly, initial intensities of the sub lights W, X, Y, and Z having different wavelengths from each other in an external light 200 can be respectively outputted. Additionally, the photoelectric conversion units 110, 120, 130, and 140 may respectively be formed in the semiconductor layers 105, 115, 125, and 135 having respectively different combination ratios or semiconductors. At this point, the buffer layers 112, 122, and 132 are respectively disposed between the semiconductor layers 105, 115, 125, and 135. The buffer layers 112, 122, and 132 alleviate stresses between the semiconductor 105, 115, 125, and 135. Accordingly, the semiconductor 105, 115, 125, and 135 can have sufficient thicknesses. As the thicknesses of the photoelectric conversion units 110, 120, 130, and 140 increase, an absorption rate for the external light 200 of the photoelectric conversion units 110, 120, 130, and 140 increases. Due to the buffer layers 112, 122, and 312, the semiconductor layers 105, 115, 125, and 135 can obtain the sufficient thicknesses. Consequently, thicknesses of the photoelectric conversion units 110, 120, 130, and 140 increase, thereby increasing an absorption rate of the external light 200.

As described above, the first semiconductor layer 105 may be formed of silicon, and the fourth semiconductor layer 135 may be formed of germanium. Silicon can absorb light having a wavelength of less than about 1.1 m. Unlike this, germanium can absorb light having the maximum value of about 1.9 m. Silicon-germanium can absorb light having a wavelength of more than about 1.1 m and less than about 1.9 m according to a germanium concentration. The photodetector may be used in an optical communication system using light, an image sensor, and a system using another light.

Next, a method of forming a photodetector according to an embodiment of the present invention will be described with reference to the drawings.

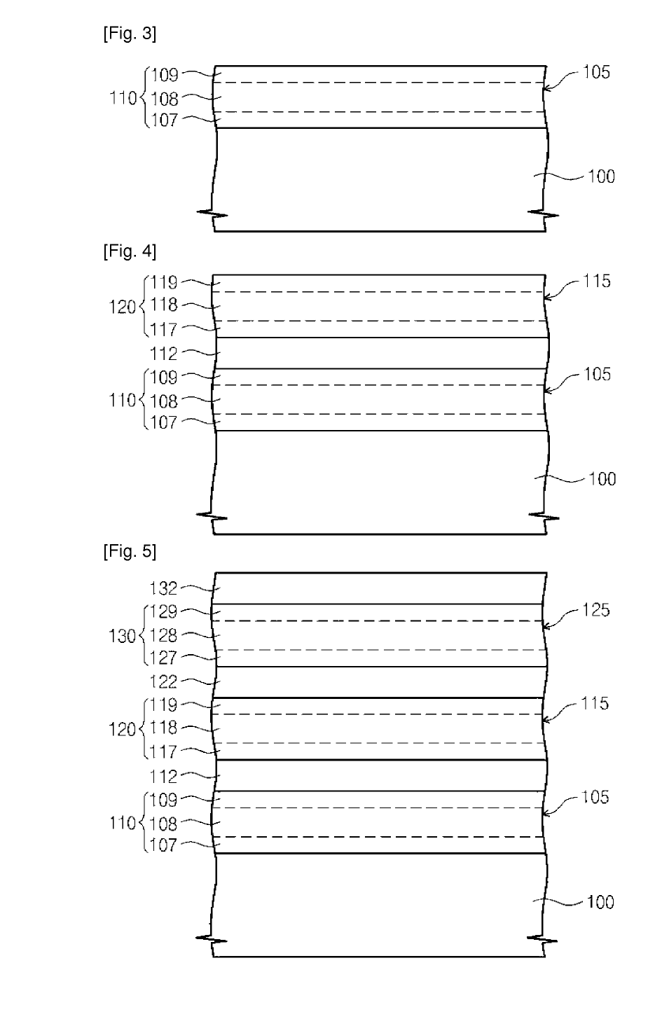

FIGS. 3 through 5 are sectional views illustrating a method of forming a photo-detector according to an embodiment of the present invention.

Referring to FIG. 3, a first semiconductor layer 105 is formed on a substrate 100 and a first photoelectric conversion unit 110 is formed in the semiconductor layer 105. The first semiconductor layer is formed of a first semiconductor. The first semiconductor layer 105 may be in a single or poly crystal state. For example, the semiconductor layer 10 For example, the semiconductor layer 105 may be formed of silicon. The substrate 100 may be a silicon substrate. At this point, the first semiconductor layer 105 may be an upper portion of the substrate 100. Unlike this, the first semiconductor layer 105 may be a silicon layer that is formed on the substrate 100 through an epitaxial growth process. The first photoelectric conversion unit 110 includes a first doped region 107 and a second doped region 109, and also further include an intrinsic region 108 interposed between the first and second doped regions 107 and 109.

The first and second doped regions 107 and 109 may be formed through an ion implantation process. That is, a first conductive type of dopant ions are implanted on a lower portion of the first semiconductor layer 105 to form the first doped region 107, and a second conductive type of dopant ions are implanted on n upper portion of the first semiconductor layer 105 to form the second doped region 107. Unlike this, the first and second doped regions 107 and 109 may be formed in-situ together with the semiconductor layer 105. That is, during an initial deposition stage of the first semiconductor layer 105, a first dopant source gas including a first conductive dopants is supplied together with a semiconductor source gas, and during a middle deposition process, only the semiconductor source gas is supplied. During a last deposition process, a second dopant source gas including a second conductive type dopants are supplied together with the semiconductor source gas. Therefore, the first semiconductor layer 105, the first doped region, the intrinsic region 108, and the second doped region 109 are formed in-situ.

Referring to FIG. 4, a first buffer layer 112 is formed on the first semiconductor layer 105. The first buffer layer 112 may be formed of a hetero-semiconductor including the first semiconductor and the second semiconductor. For example, the first buffer layer 112 may be formed of silicon-germanium. The first buffer layer 112 may be formed an epitaxial growth process. The first buffer layer 112 is formed through a deposition process using a first semiconductor source gas (e.g., silicon source gas) and a second semiconductor source gas (e.g., germanium source gas). At this point, supply of the second semiconductor source gas may gradually increase. Accordingly, a second semiconductor concentration of the first buffer layer 112 gradually increases far from the bottom surface of the first buffer layer 112.

A second semiconductor layer 115 is formed on the first buffer layer 112 and a second photoelectric conversion unit 120 is formed in the second semiconductor layer 115. The second semiconductor layer 115 is formed of a hetero semiconductor including the first and second semiconductors. For example, the second semiconductor layer 115 is formed of silicon-germanium. The second semiconductor concentration (e.g., a germanium concentration) may be uniform over the entire second semiconductor layer 115. That is, while the second semiconductor layer 115 is deposited, supply amount of a first semiconductor source gas (e.g., silicon source gas) and a second semiconductor source gas (e.g., germanium source gas) may be uniform. The second semiconductor source gas (e.g., germanium source gas) in the second semiconductor layer 115 may be the same as the second semiconductor concentration at the upper surface of the first buffer layer 112. Because the second semiconductor layer 115 is formed by an epitaxial process, it may be a single crystal state. Unlike this, the second semiconductor layer 115 may be in a poly crystal state.

The second photoelectric conversion unit 120 includes a first doped region 117 and a second doped region 119, and may further include an intrinsic region 118 interposed between the first and second doped regions 117 and 119. The first and second doped regions 117 and 119 of the second photoelectric conversion unit 120 may be formed through an ion implantation process. Unlike this, the first and second doped regions 117 and 119 of the second photoelectric conversion unit 120 may be formed in-situ together with the deposition process of the second semiconductor layer 115.

Referring to FIG. 5, a second buffer layer 122 is formed on the second semiconductor layer 115. The second buffer layer 122 may be formed of a hetero-semiconductor including the first semiconductor and the second semiconductor. For example, the second buffer layer 122 may be formed of silicon-germanium. At this point, supply of a second semiconductor source gas (e.g., germanium source gas) may gradually increase. Accordingly, a supply amount of the second semiconductor concentration gradually increases far from the bottom surface of the second buffer layer 122. The second semiconductor source at the bottom surface of the second buffer layer 122 is the same as the second semiconductor layer 115.

A third semiconductor layer 125 is formed on the second buffer layer 122, and a third photoelectric conversion unit 130 is formed in the third semiconductor layer 135. The third semiconductor layer 125 may be formed of a hetero semiconductor including the first and second semiconductors. For example, the third semiconductor layer 125 may be formed of silicon-germanium. The entire third semiconductor layer 125 has a uniform second semiconductor concentration (e.g., a germanium concentration). The second semiconductor concentration of the third semiconductor layer 125 is the same as the second semiconductor concentration at the top surface of the second buffer layer 122. The third photoelectric conversion unit 130 includes a first doped region 127 and a second doped region, and further includes an intrinsic region interposed therebetween. The first and second doped regions 127 and 129 may be formed by an ion implantation method or an in-situ method.

A first buffer layer 132 is formed on the third semiconductor layer 125. The third buffer layer 132 may be formed of a hetero semiconductor including the first and second semiconductors. For example, the third buffer layer 132 may be formed of silicon-germanium. The second semiconductor concentration (e.g., a germanium concentration) of the third buffer layer 132 gradually increases far away from the bottom surface of the third buffer layer 132. The second semiconductor concentration at the bottom surface of the third buffer layer 132 is the same as the second semiconductor concentration of the third semiconductor layer 125.

The fourth semiconductor layer 135 of FIG. 1 is formed in the third buffer layer 132 and a fourth photoelectric conversion unit 140 is formed in the fourth semiconductor layer 135. The fourth semiconductor layer 135 may be formed of a hetero semiconductor including the first and second semiconductors. For example, the fourth semiconductor layer 135 may be formed of silicon-germanium. The second semiconductor concentration (e.g., a germanium concentration) of the fourth semiconductor layer 135 may be the same as the second semiconductor concentration at the top surface of the third buffer layer 132. The first doped region 137 and the second doped region 139 of the fourth photoelectric conversion unit 140 may be formed by an ion implantation method or an in-situ method.

The buffer layers 112, 122, and 132 may be formed of silicon-germaniums of different composition ratios from each other. The buffer layers 112, 122, and 132 may be formed at a process temperature ranging from about 800° C. to about 900° C. Additionally, the buffer layers 112, 122, and 132 may be formed at a process pressure of about 1 torr to about 100 torr. The first and second semiconductor source gases for the buffer layers 112, 122, and 132 may be supplied to a deposition chamber together with a carrier gas such as hydrogen or helium.

In a case where the photoelectric conversion units 110, 120, 130, and 140 are formed in-situ and the first semiconductor layer 105 is formed through an epitaxial process, the semiconductor layers 105, 115, 125, and 135, the photoelectric conversion units 110, 120, 130, and 140, and the buffer layers 112, 122, and 132 can be continuously formed in one deposition chamber. After loading the substrate 100 into one deposition chamber, the semiconductor layers 105, 115, 125, and 135, the photoelectric conversion units 110, 120, 130, and 140, and the buffer layers 112, 122, and 132 can be continuously formed by adjusting supply amount of the first semiconductor source gas, the second semiconductor source gas, and the first and second dopant source gases.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1. A photodetector comprising:
a plurality of semiconductor layers sequentially stacked on a substrate;
a plurality of photoelectric conversion units formed in the semiconductor layers, respectively, and having different spectral sensitivities from each other; and
buffer layers interposed between the adjacent semiconductor layers, respectively, wherein each of the buffer layers alleviates stress between the adjacent semiconductor layers.

2. The photodetector of claim 1, wherein the lowermost semiconductor layer among the semiconductor layers is formed of a first semiconductor, and the uppermost semiconductor layer among the semiconductors is formed of a second semiconductor,
wherein at least one semiconductor layer interposed between the lowest and uppermost semiconductor layers comprises a hetero-semiconductor including the first and second semiconductors.

3. The photodetector of claim 2, wherein the lowermost semiconductor layer is formed of silicon;
the uppermost semiconductor layer is formed of germanium; and
the interposed semiconductor layer is formed of silicon-germanium.

4. The photodetector of clam 3, wherein the entire interposed semiconductor layer comprises a uniform a germanium concentration.

5. The photodetector of claim 3, wherein each of the buffer layers is formed of silicon-germanium, and a germanium concentration of each of the buffer layers gradually increases farther away from a bottom surface of each of the buffer layers.

6. The photodetector of claim 5, wherein a germanium concentration at the bottom surface of each of the buffer layers is the same as a germanium concentration of the semiconductor layer right below each of the buffer layers; and
a germanium concentration at the top surface of each of the buffer layers is the same as a germanium concentration of the semiconductor layer right above each of the buffer layers.

7. The photodetector of claim 1, wherein each of the photoelectric conversion units comprises an N-doped region and a P-doped region in each of the semiconductor layers.

8. The photodetector of claim 7, wherein each of the photoelectric conversion units further comprises an intrinsic region interposed between the N-doped region and the P-doped region.

9. The photodetector of claim 1, wherein the lowermost semiconductor layer among the semiconductor layers is formed of a first semiconductor, and the uppermost semiconductor layer among the semiconductor layers is formed of a second semiconductor,
wherein a plurality of the semiconductor layers are interposed between the lowest and the uppermost semiconductors, and
wherein each of the interposed semiconductor layers comprises a hetero-semiconductor including the first and second semiconductors, the interposed semiconductor layers having different second semiconductor concentrations from each other.

10. The photodetector of claim 9, wherein the lowermost semiconductor layer is formed of silicon; the uppermost semiconductor layer is formed of germanium;
and the interposed semiconductor layers are formed of silicon-germanium, wherein a germanium concentration of each of the interposed semiconductor layers is uniform, and
wherein a germanium concentration of a interposed semiconductor layer relatively close to the lowermost semiconductor layer among the interposed semi-conductor layers is less than a germanium concentration of a interposed semiconductor layer relatively close to the uppermost semiconductor layer among the interposed semiconductor layers.

11. The photodetector of claim 1, further comprising a signal detection circuit electrically connected to the photoelectric conversion units.

12. The photodetector of claim 11, wherein an external light including a plurality of sub lights with different wavelengths from each other is incident to the photo-electric conversion units,
the signal detection circuit comprises:
detectors respectively connected to the photoelectric conversion units and detecting intensity of light absorbed in each of the photoelectric conversion units as an electrical signal; and
an operator calculating intensity of each of the sub lights by means of at least signals extracted by the detectors, absorption coefficients according to wavelengths of the semiconductor layers, and thicknesses of the semiconductor layers.

13. The photodetector of claim 12, wherein a sub light having the longest wavelength among the sub lights is absorbed by the photoelectric conversion unit at the highest layer among the photoelectric conversion units, and
a sub light having a shorter wavelength than the longest wavelength among the sub lights is absorbed by at least the photoelectric conversion unit at the highest layer and the photoelectric conversion unit right below the conversion unit at the highest layer.

14. A photodetector comprises:
a plurality of semiconductor layers sequentially stacked on a substrate;
a plurality of photoelectric conversion units formed in the semiconductor layers, respectively; and
buffer layers interposed between the adjacent semiconductor layers, respectively, wherein each of the buffer layers alleviates stress between the adjacent semiconductor layers and the semiconductor layers have different energy band gaps from each other.

15. The photodetector of claim 14, wherein the energy band gaps of the semiconductor layers decrease farther away from the substrate.

16. The photodetector of claim 14, wherein the lowermost semiconductor layer among the semiconductor layers is formed of silicon;
the uppermost semiconductor layer among the semiconductor layers is formed of germanium; and
at least one semiconductor layer interposed between the lowest and uppermost semiconductor layers is formed of silicon-germanium.

17. The photodetector of claim 14, wherein each of the photoelectric conversion units comprises an N-doped region and a P-doped region in each of the semiconductor layers and an intrinsic region interposed between the N-doped region and the P-doped region.
